(19) United States
(12) Patent Application Publication
(10) Pub. No.: US 2006/0270243 A1
(43) Pub. Date: Nov. 30, 2006

(54) Alignment shield for evaporator used in thin film deposition

(75) Inventors: Chung-chih Chang, Pingtung County (TW); Shun-yu Wang, Hsinchu City (TW); Ling-yuan Tseng, Saratoga, CA (US)

Correspondence Address: PATENT LAW GROUP LLP, 2635 NORTH FIRST STREET, SUITE 223, SAN JOSE, CA, 95134, US

(73) Assignee: Taiwan Micro Display Corporation

(21) Appl. No.: 11/136,812

(22) Filed: May 24, 2005

(51) Int. Cl. C23C 16/00; H01L 21/31

(52) U.S. Cl. 438/758; 118/719

(57) ABSTRACT

A system for depositing film includes (1) a substrate holder assembly, (2) a particle source, (3) an alignment shield between the particle source and the substrate holder assembly, and (4) a vacuum chamber for enclosing the substrate holder assembly, the particle source, and the alignment shield. The alignment shield includes alignment cells each having walls that can be individually adjusted to change the oblique deposition angles. By adjusting the walls of the alignment cells, uniform oblique deposition angles can be achieved on substrates held by the substrate holder assembly. The deposited film with uniform orientation can be used as the alignment layer of a liquid crystal display.

### FIELD OF INVENTION

This invention relates to an evaporator for depositing film with a uniform orientation to form an alignment layer for a liquid crystal display.

### DESCRIPTION OF RELATED ART

Thin film deposition refers to a process that coats a thin layer of film on a substrate. Thin film deposition includes sputtering, evaporation, and chemical vapor deposition. Thin film deposition is generally concerned with the thickness and the uniformity of the film, and not the alignment orientation of the thin film.

On a liquid crystal display (LCD), there are alignment layers above and below the liquid crystal that control the alignment of the liquid crystal molecules. The surfaces of the alignment layers have the proper geometric patterns to fix the liquid crystal molecules along the desired directions. An alignment layer can be polyimide that is spun onto a substrate and then mechanically rubbed to form microgrooves along the desired direction. The liquid crystal molecules mount onto the microgrooves along the desired direction. The alignment layer can also be silicon dioxide that is deposited onto a substrate at an oblique angle to form the microgrooves.

One of the most popular LCD display is the vertically aligned nematic (VAN) display. In the VAN display, the liquid crystal molecules are aligned almost perpendicular to the surface with a small pre-tilt angle at the off state. To improve respond speed and contrast, the alignment layers are formed with a uniform pre-tilt angle. Depending on the design, the pre-tilt angle ranges between 0.5 to 10 degrees.

In a conventional evaporator, an electron gun irradiates a target material in a crucible within a vacuum chamber. Once heated, the target material evaporates and the evaporated particles attach to a substrate suspended to form a thin film. However, the upward directions of the evaporated particles vary. This makes it difficult to form a VAN alignment layer having a uniform pre-tilt angle. It is especially difficult during a mass production process where many substrates hang inside the vacuum chamber. The alignment directions of the thin films on the substrates will differ according to each substrate's position and height, thereby adversely affecting the uniformity of the LCD displays.

Thus, what is needed is an apparatus to evaporate a film with uniform alignment orientation onto a substrate.

### SUMMARY

In one embodiment of the invention, a system for depositing film includes (1) a substrate holder assembly, (2) a particle source, (3) an alignment shield between the particle source and the substrate holder assembly, and (4) a vacuum chamber for enclosing the substrate holder assembly, the particle source, and the alignment shield. The alignment shield includes alignment cells each having walls that can be individually adjusted to change the oblique deposition angles. By adjusting the walls of the alignment cells, uniform oblique deposition angles can be achieved on substrates held by the substrate holder assembly. The deposited film with uniform orientation can be used as the alignment layer of a liquid crystal display.

### BRIEF DESCRIPTION OF THE DRAWINGS

FIG. 1 illustrates an evaporator in one embodiment of the invention.

FIG. 2 illustrates a substrate holder assembly in the evaporator of FIG. 1 in one embodiment of the invention.

FIGS. 3 and 4 illustrate an alignment shield in the evaporator of FIG. 1 in one embodiment of the invention.

FIG. 5 illustrates an evaporator in one embodiment of the invention.

Use of the same reference numbers in different figures indicates similar or identical elements.

### DETAILED DESCRIPTION

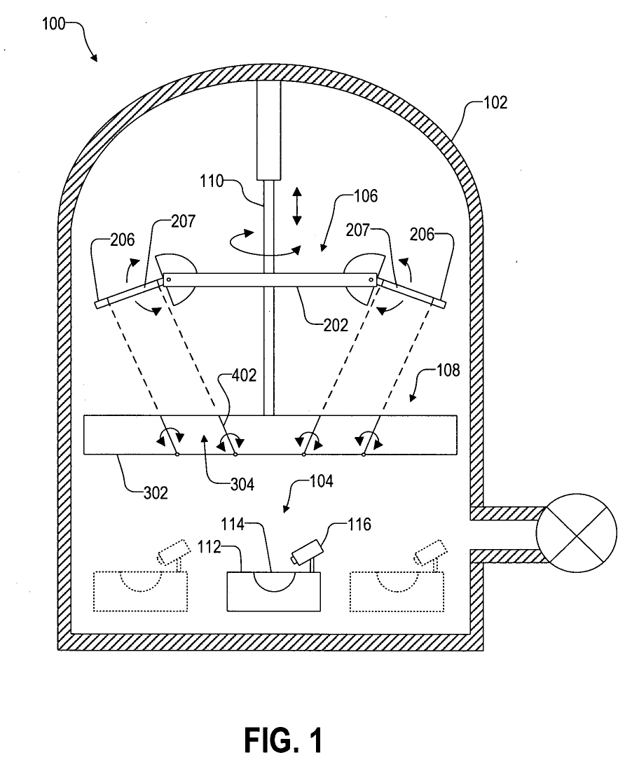

FIG. 1 illustrates a system 100 (e.g., an evaporator) for depositing film in one embodiment of the invention. Evaporator 100 includes a vacuum chamber 102 enclosing (1) a particle source 104, (2) a substrate holder assembly 106, and (3) an alignment shield 108 between particle source 104 and substrate holder assembly 106. Substrate holder assembly 106 and alignment shield 108 are supported by an adjustable column 110. Thus, the distance between particle source 104 and substrates 207 suspended by substrate holder assembly 106 is adjustable.

Particle source 104 (e.g., an evaporation source) includes a crucible 112 for holding a target material 114 (e.g., silicon dioxide), and an electron gun 116 for heating target material 114. Although only one evaporation source is shown, multiple evaporation sources can be used. Each evaporation source may employ its own electron gun or share a common electron gun where the crucibles are transported to the electron gun. Typically silicon dioxide is evaporated onto a silicon substrate or an indium tin oxide (ITO) glass wafer to form the alignment layer of a liquid crystal display (e.g., a VAN display).

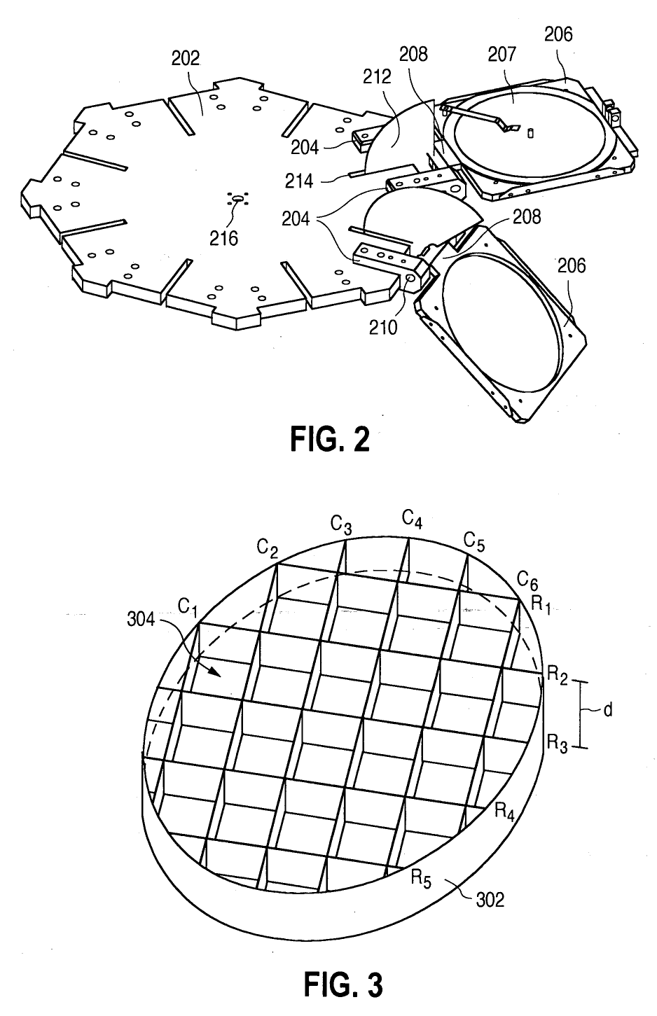

FIG. 2 illustrates the details of substrate holder assembly 106 in one embodiment of the invention. Assembly 106 includes an octagon base plate 202. Base plate 202 defines a bore 216 for receiving support column 110. Clamps 204 are mounted on each side of base plate 202 to receive a substrate holder 206. Substrate holder 206 has a knuckle 208 inserted between clamps 204 and held in place by a pin 210. Substrate holder 206 can be adjusted by pivoting up and down relative to base plate 202, thereby setting the oblique deposition angle for a substrate held by substrate holder 206. An angle indicator 212 is mounted to knuckle 208 and passes through a slot 214 in base plate 202. Typically substrate holder 206 holds a silicon wafer 207 or an ITO glass wafer 207.

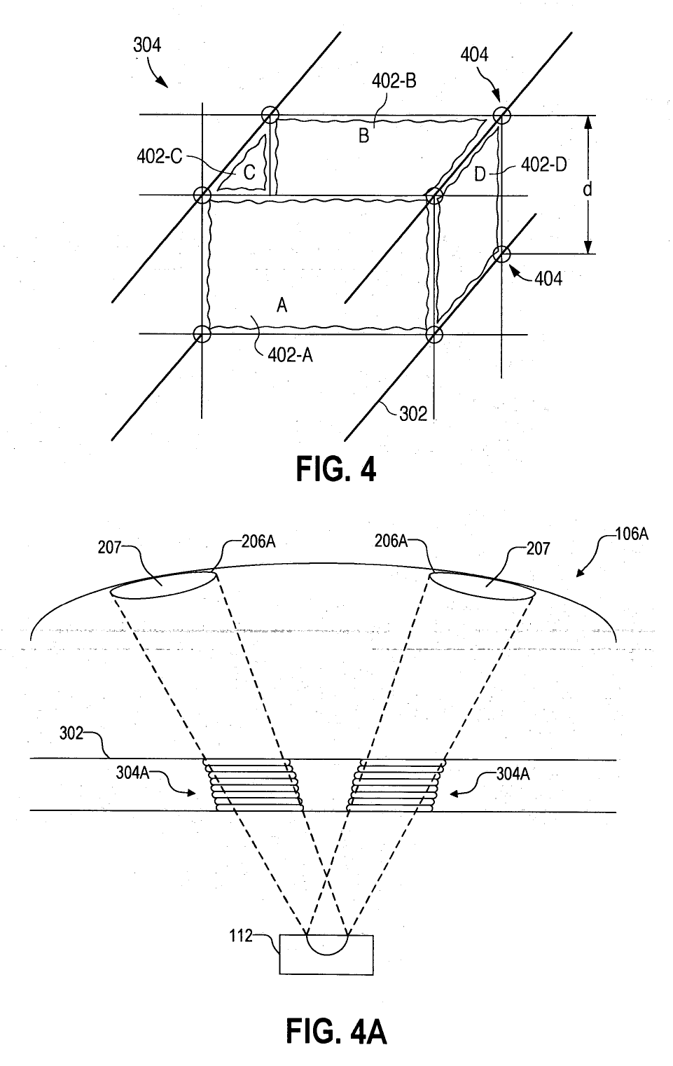

FIG. 3 illustrates the details of alignment shield 108 in one embodiment of the invention. Alignment shield 108 includes a frame 302 having columns C1 to C5 and rows R1 to R5. Individual alignment cells 304 (only one is labeled) are formed on the columns and rows. Each alignment cells 304 is adjusted to provide a desired deposition for a corresponding substrate.

FIG. 4 illustrates an alignment cell 304 in one embodiment of the invention. In one embodiment, alignment cell 304 has four adjustable walls 402-A, 402-B, 402-C, and 402-D (collectively wall 402) having a height d. Walls 402 are mounted by top or bottom hinges 404 to the columns and rows of frame 302. Walls 402 can be adjusted by pivoting them relative to frame 302, thereby setting the oblique deposition angle.

The distance between each substrate 207 to evaporation source 104 may be different. Furthermore, the position of each substrate 207 relative to evaporation source 104 may be different. In addition, the distance between evaporation source 104 and substrate holder assembly 106 may be adjusted to achieve a desired deposition rate. All these factors affect the oblique deposition angle and the pre-tilt angle of the resulting alignment layer.

These factors can be easily addressed by alignment shield 108 with individually adjustable alignment cells 302. Each alignment cell 302 is tailored for one corresponding substrate. Each substrate may receive evaporated particles from a single alignment cell 302 or from a group of alignment cells 302. Accordingly, alignment layers with uniform pro-tilt angle can be formed on each of the substrates.

The dimensions of the columns and rows and the height of the walls depend on the actual dimensions of evaporator 100. In general, the dimensions of the columns and rows can be decreased and the height of the walls can be increased to limit the evaporated particle trajectories that pass through alignment cells 304, thereby reducing the variation in the oblique deposition angle. The distance between substrates 207 suspended by substrate holder assembly 106 and evaporation source 104 can be increased to limit the variation in the oblique deposition angle. The distance between alignment shield 108 and evaporation source 104 can be increased to limit the variation in the oblique deposition angle.

FIG. 4A illustrates another type of alignment cell 304 (hereafter alignment cell 304A) in one embodiment of the invention. Alignment cell 304A is a flexible metal hose that can be bent to set the oblique deposition angle. Alignment cell 304A holds its shape between adjustments. The flexible metal hose can be implemented similar to ventilation hoses for dryers and bendable straws. In one embodiment, the flexible metal hose is made of thin aluminum having a thickness of about 0.5 millimeter.

As described before, each alignment cell 304A is individually tailored for one corresponding substrate to compensate for the varying distances between that substrate and evaporation source 104 and for the position that substrate relative to evaporation source 104. Each substrate may receive evaporated particles from a single alignment cell 302A or from a group of alignment cells 302A. Accordingly, alignment layers with uniform pre-tilt angle can be formed on each of the substrates.

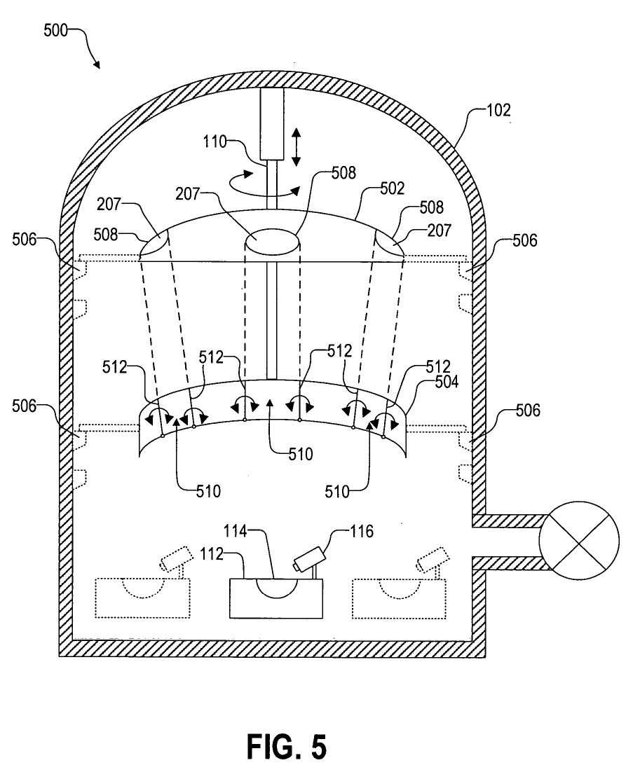

FIG. 5 illustrates an evaporator 500 in one embodiment of the invention. Evaporator 500 includes vacuum chamber 102 enclosing (1) evaporation source 104, (2) a substrate holder assembly 502, and (3) an alignment shield 504 between evaporation source 104 and substrate holder assembly 502. Substrate holder assembly 502 and alignment shield 504 are supported by an adjustable column 110. Thus, the distance between evaporation source 104 and substrates 207 suspended by substrate holder assembly 502 is adjustable. Alternatively, substrate holder assembly 502 and alignment shield 504 may be suspended on brackets 506 on the inner sidewall of vacuum chamber 102.

Evaporation source 104 includes crucible 112 for holding target material 114, and electron gun 116 for heating target material 114. Although only one evaporation source is shown, multiple evaporation sources can be used.

Substrate holder assembly 502 may have a dome shape with individual substrate holders 508 for holding the substrates. Alignment shield 504 has a dome shape similar to substrate holder 502 to provide a better correspondence between alignment cells 510 and the substrates. As described above with alignment cells 304, each alignment cell 510 has four adjustable walls 512 that can be adjusted to provide the desired oblique deposition angle.

Various other adaptations and combinations of features of the embodiments disclosed are within the scope of the invention. For example, alignment cells can have a hexagon shape with six walls. Furthermore, the alignment shield can have any shape that matches the shape of the substrate holder. Numerous embodiments are encompassed by the following claims.

What is claimed is:

1. An system for depositing film, comprising:
a substrate holder assembly for holding a plurality of substrates;
a particle source for generating particles toward the substrate holder assembly;
an alignment shield between the particle source and the substrate holder assembly, the alignment shield comprising a plurality of individually adjustable alignment cells, each alignment cell being adjustable to provide a corresponding deposition angle to one corresponding substrate; and
a vacuum chamber enclosing the substrate holder assembly, the particle source, and the alignment shield.

2. The system of claim 1, wherein each alignment cell comprises walls that are pivotally mounted to a frame of the alignment shield.

3. The system of claim 1, wherein each alignment cell comprises a flexible metal hose that bends to set the corresponding deposition angle.

4. The system of claim 1, wherein the substrate holder assembly comprises:
a base;
a plurality of substrate holders mounted to the base, wherein the substrate holders can adjust to change their corresponding deposition angles.

5. The system of claim 2, wherein the substrate holders are pivotally mounted to the base.

6. The system of claim 1, wherein the substrate holder assembly and the alignment shield each have a dome shape.

7. The system of claim 1, wherein the particle source comprises a crucible and an electron gun for heating the material in the crucible.

8. The system of claim 1, wherein the particle source comprises (1) a plurality of crucibles corresponding to the substrate holders, and (2) a plurality of electron guns corresponding to the crucibles for heating the material in the crucibles.

9. The system of claim 1, further comprising a column supporting the base, the column setting a height of the substrate holder assembly in the vacuum chamber.

10. A method for forming alignment layers on substrates, comprising:
adjusting a plurality of alignment cells on an alignment shield to provide proper deposition angles on a plurality of substrates held by a substrate holder assembly, wherein each alignment cell is adjusted for one substrate; and
generating particles with a particle source toward the substrates, wherein the particles pass through the alignment cells and deposits on the substrates.

11. The method of claim 10, wherein said adjusting a plurality of alignment cells comprises pivoting walls of the alignment cells.

12. The method of claim 10, wherein the alignment cells comprise flexible metal hoses and said adjusting a plurality of alignment cells comprises bending the flexible metal hoses.

13. The method of claim 10, further comprising:
adjusting a distance between the substrate holder assembly and the particle source; and
readjusting the alignments cells to provide the proper deposition angles on the substrates.

14. The method of claim 10, further comprising:
adjusting a distance between the alignment shield and the particle source.
